(19) United States
(12) Patent Application Publication
(10) Pub. No.: US 2025/0300087 A1
(43) Pub. Date: Sep. 25, 2025

(54) SYSTEMS, METHODS, AND DEVICES FOR SEMICONDUCTOR PACKAGING WITH STACKED DEVICES HAVING POWER DELIVERY NETWORK

(71) Applicant: Samsung Electronics Co., Ltd., Suwon-si (KR)

(72) Inventors: Yan LI, Morgan Hill, CA (US); WooPoung KIM, San Jose, CA (US)

(21) Appl. No.: 19/075,766

(22) Filed: Mar. 10, 2025

Related U.S. Application Data
(60) Provisional application No. 63/567,881, filed on Mar. 20, 2024.
(60) Provisional application No. 63/567,887, filed on Mar. 20, 2024.

(51) Int. Cl. H01L 23/538; H01L 25/16; H10B 80/00

(52) U.S. Cl. CPC H01L 23/5386; H01L 25/16; H10B 80/00

(57) ABSTRACT

A device may include an interface die, a first memory device stack connected to a first side of the interface die, a second memory device stack connected to the first side of the interface die, and a power distribution network located on a second side of the interface die. A system may include a substrate comprising at least one distribution layer, a compute die connected to the at least one distribution layer, and a memory stack device connected to the at least one distribution layer, wherein the memory stack device may include an interface die connected to the at least one distribution layer, a first stack of memory devices connected to the interface die, and a second stack of memory devices connected to the interface die. The substrate may include an attachment location, and the compute die may be located within the attachment location.

### REFERENCE TO RELATED APPLICATION

This application claims priority to, and the benefit of, U.S. Provisional Patent Application Ser. No. 63/567,881 filed Mar. 20, 2024 and U.S. Provisional Patent Application Ser. No. 63/567,887 filed Mar. 20, 2024, both of which are incorporated by reference.

### TECHNICAL FIELD

This disclosure relates generally to semiconductor packaging, and more specifically to systems, methods, and devices for semiconductor packaging with stacked devices having a power delivery network.

### BACKGROUND

Some semiconductor packaging techniques may involve combining multiple integrated circuit devices in a package. For example, different types of integrated circuits such as memory devices, processing devices, and/or the like, may be fabricated on separate semiconductor dies using different processes. The dies may be physically and/or electrically connected using various substrates, interposers, interconnects, and/or the like, and enclosed in a package to provide physical, thermal, and/or electrical protection.

The above information disclosed in this Background section is only for enhancement of understanding of the background of the inventive principles and therefore it may contain information that does not constitute prior art.

### SUMMARY

A device may include an interface die, a first memory device stack connected to a first side of the interface die, a second memory device stack connected to the first side of the interface die, and a power distribution network located on a second side of the interface die. The power distribution network may include a layer of conductive traces, and a via arranged to transfer power using the layer of conductive traces. The interface die may include a buffer circuit configured to access the first memory device stack, and a processing circuit configured to perform an operation on data stored in the first memory device stack.

A system may include a substrate comprising at least one distribution layer, a compute die connected to the at least one distribution layer, and a memory stack device connected to the at least one distribution layer, wherein the memory stack device may include an interface die connected to the at least one distribution layer, a first stack of memory devices connected to the interface die, and a second stack of memory devices connected to the interface die.

The substrate may include an attachment location, and the compute die may be located within the attachment location. The substrate may include an attachment location, the compute die may be located within the attachment location, the memory stack device may be connected to a first side of the distribution layer, and the compute die may be connected to a second side of the distribution layer. The memory stack device may be a first memory stack device, the system may further include a second memory stack device connected to the first side of the distribution layer, and the compute die may be configured to connect the first memory stack device to the second memory stack device. The substrate may include an attachment location, and the memory stack device may be located within the attachment location. The substrate may include a first attachment location and a second attachment location, the compute die may be located in the first attachment location, and the memory stack device may be located in the second attachment location. The first stack of memory devices may be connected to a first side of the interface die, the second stack of memory devices may be connected to the first side of the interface die, the memory stack device may include a power distribution network located on a second side of the interface die, and the power distribution network may be connected to the at least one distribution layer. One of the at least one distribution layer may be located at a first side of the substrate, and the substrate may include a thermal structure located at a second side of the substrate.

The memory stack device may be a first memory stack device, the system further may include a second memory stack device, the first memory stack device may be located at a first side of the substrate, and the second memory stack device may be located at a second side of the substrate. The substrate may include an attachment location. The system further may include a connecting element located within the attachment location, and the connecting element may be configured to connect the compute die and the first memory stack device. The substrate may include an attachment location, and the first memory stack device may be located within the attachment location. The substrate may include a first attachment location and a second attachment location, the compute die may be located in the first attachment location, and the memory stack device may be located in the second attachment location. The substrate may be a first substrate, the system may further include a second substrate located between the first substrate and the second memory stack device, wherein the second substrate may include an attachment location, and a third memory stack device located within the attachment location. The substrate may be a first substrate, the system may further include a second substrate located between the first substrate and the second memory stack device, wherein the second substrate may include an attachment location, and at least one of a compute die, connecting element, or power device located within the attachment location.

A method may include forming, on a substrate, at least one distribution layer, connecting, to the at least one distribution layer, a compute die, and connecting, to the at least one distribution layer, a memory stack device comprising an interface die connected to the at least one distribution layer, a first stack of memory devices connected to the interface die, and a second stack of memory devices connected to the interface die. The method may further include forming, on a first side of the interface die, a power delivery network, attaching, to a second side of the interface die, the first stack of memory devices, and attaching, to the second side of the interface die, the second stack of memory devices. The memory stack device may be a first memory stack device, the method may further include positioning, at a first side of the substrate, the first memory device stack, and positioning, at a second side of the substrate, a second memory device stack.

### BRIEF DESCRIPTION OF THE DRAWINGS

The figures are not necessarily drawn to scale and elements of similar structures or functions or portions thereof may generally be represented by reference indicators ending in, and/or containing, the same digits, letters, and/or the like, for illustrative purposes throughout the figures. The figures are only intended to facilitate the description of the various embodiments described herein. The figures do not describe every aspect of the teachings disclosed herein and do not limit the scope of the claims. To prevent the drawings from becoming obscured, not all of the components, connections, and the like, may be shown, and not all of the components may have reference numbers. However, patterns of component configurations may be readily apparent from the drawings. The accompanying drawings, together with the specification, illustrate example embodiments of the present disclosure, and, together with the description, serve to explain the principles of the present disclosure.

FIG. 1A illustrates an embodiment of a package architecture including a multi-stack memory device in accordance with example embodiments of the disclosure.

FIG. 1B illustrates a cross-section taken through dot-dashed line A-A of the package architecture in FIG. 1A.

FIG. 2A illustrates a cross-sectional view of an embodiment of a multi-stack memory device having a power delivery network in accordance with example embodiments of the disclosure.

FIG. 2B illustrates an enlarged view of a portion of the cross-sectional view of the embodiment of a multi-stack memory device illustrated in FIG. 2A.

FIG. 3A illustrates a plan view of an embodiment of a package architecture including one or more multi-stack memory devices and a substrate with one or more embedded components in accordance with example embodiments of the disclosure.

FIG. 3B illustrates a cross-sectional view of the package architecture illustrated in FIG. 3A taken through dot-dashed line A-A in accordance with example embodiments of the disclosure.

FIG. 4A illustrates a cross-sectional view of one or more operations for forming one or more thermal structures in an embodiment of a method for fabricating a package architecture in accordance with example embodiments of the disclosure.

FIG. 4B illustrates a cross-sectional view of one or more operations for forming one or more cavities in an embodiment of a method for fabricating a package architecture in accordance with example embodiments of the disclosure.

FIG. 4C illustrates a cross-sectional view of one or more operations for forming one or more backside films in an embodiment of a method for fabricating a package architecture in accordance with example embodiments of the disclosure.

FIG. 4D illustrates a cross-sectional view of one or more operations for positioning one or more embedded components in an embodiment of a method for fabricating a package architecture in accordance with example embodiments of the disclosure.

FIG. 4E illustrates a cross-sectional view of one or more operations for forming one or more films, laminations, and/or the like, in an embodiment of a method for fabricating a package architecture in accordance with example embodiments of the disclosure.

FIG. 4F illustrates a cross-sectional view of one or more operations for forming one or more distribution layers in an embodiment of a method for fabricating a package architecture in accordance with example embodiments of the disclosure.

FIG. 4G illustrates a cross-sectional view of one or more operations for positioning one or more components on a substrate or distribution layer in an embodiment of a method for fabricating a package architecture in accordance with example embodiments of the disclosure.

FIG. 4H illustrates a cross-sectional view of one or more operations for forming one or more thermal structures in an embodiment of a method for fabricating a package architecture in accordance with example embodiments of the disclosure.

FIG. 5 illustrates an embodiment of a package architecture having a multi-stack memory device embedded in a substrate in accordance with example embodiments of the disclosure.

FIG. 6A illustrates a plan view of an embodiment of a package architecture including multi-stack memory devices on two sides of a substrate with one or more embedded components in accordance with example embodiments of the disclosure.

FIG. 6B illustrates a cross-sectional view of the package architecture illustrated in FIG. 6A taken through dot-dashed line A-A in accordance with example embodiments of the disclosure.

FIG. 7A illustrates a cross-sectional view of one or more operations for forming one or more thermal structures in an embodiment of a method for fabricating a package architecture in accordance with example embodiments of the disclosure.

FIG. 7B illustrates a cross-sectional view of one or more operations for forming one or more cavities in an embodiment of a method for fabricating a package architecture in accordance with example embodiments of the disclosure.

FIG. 7C illustrates a cross-sectional view of one or more operations for forming one or more backside films in an embodiment of a method for fabricating a package architecture in accordance with example embodiments of the disclosure.

FIG. 7D illustrates a cross-sectional view of one or more operations for positioning one or more embedded components in an embodiment of a method for fabricating a package architecture in accordance with example embodiments of the disclosure.

FIG. 7E illustrates a cross-sectional view of one or more operations for forming one or more films, laminations, and/or the like, in an embodiment of a method for fabricating a package architecture in accordance with example embodiments of the disclosure.

FIG. 7F illustrates a cross-sectional view of one or more operations for forming one or more distribution layers in an embodiment of a method for fabricating a package architecture in accordance with example embodiments of the disclosure.

FIG. 7G illustrates a cross-sectional view of one or more operations for positioning one or more components on a first side of a substrate and a second side of a substrate in an embodiment of a method for fabricating a package architecture in accordance with example embodiments of the disclosure.

FIG. 7H illustrates a cross-sectional view of one or more operations for forming one or more thermal structures in an embodiment of a method for fabricating a package architecture in accordance with example embodiments of the disclosure.

FIG. 8 illustrates an embodiment of a package architecture having components on two sides of a substrate and a multi-stack memory device embedded in the substrate in accordance with example embodiments of the disclosure.

FIG. 9 illustrates an embodiment of a package architecture having two or more substrates in accordance with example embodiments of the disclosure.

### DETAILED DESCRIPTION

Some semiconductor packaging techniques may combine 2.5D techniques (in which devices may be arranged horizontally on an interposer, substrate, and/or the like) and 3D techniques (in which devices may be stacked vertically). For example, a multi-stack memory device may include two or more stacks of vertically stacked memory dies. The stacks may be arranged side-by-side on an interface die that may include buffer circuitry (e.g., for accessing data stored in the stacks), logic circuitry (e.g., for processing data stored in the stacks), and/or the like.

A multi-stack memory device as described above may enable a relatively large number of memory dies to be fabricated in a compact assembly with a relatively large amount of interface circuitry (e.g., in an interface die). However, providing stable, reliable power to the components in such an assembly may be difficult because they may consume a relatively large amount of power through a power delivery network that may be routed in a complex arrangement with signal layers in the interface die.

Some aspects of the disclosure relate to a multi-stack memory device having a power delivery network on a first side (e.g., a back side) of an interface die and two or more stacks of memory dies on a second side (e.g., a front side) of the interface die. In some embodiments, this may improve the performance of a power delivery network, for example, by at least partially separating one or more layers of power traces from one or more layers of signal traces.

Some additional aspects of the disclosure relate to techniques for combining one or more multi-stack memory devices with other components in a package using one or more substrates having one or more embedded components. The one or more embedded components may include one or more multi-stack memory devices, compute dies, power conditioning devices (e.g., capacitors, voltage regulation modules, and/or the like), connecting elements (e.g., bridges), and/or the like or combinations thereof.

For example, in some embodiments, a compute die may be embedded in a substrate and connected through a redistribution layer (RDL) to a multi-stack memory device located on top of the substrate. Depending on the implementation details (e.g., the multi-stack memory device may be located at least partially over the compute die), this configuration may result in relatively short die to die connections between the multi-stack memory device and the compute die, thereby increasing bandwidth, reducing signal delay, reducing power consumption, and/or the like. Additionally, or alternatively, the compute die may be configured to operate as a bridge (e.g., an active bridge) between the multi-stack memory device and a second multi-stack memory device located on top of the substrate. Depending on the implementation details, this may provide efficient die to die connections between the multi-stack memory devices, thereby accommodating more multi-stack memory devices within a package.

Additionally, or alternatively, one or more power conditioning devices such as capacitors and/or voltage regulation modules may be embedded in the substrate. Depending on the implementation details, this may improve the performance of a power delivery network (PDN) on the multi-stack memory device because, for example, the one or more power conditioning devices may be located relatively close to the multi-stack memory device.

As a further example, in some embodiments, a multi-stack memory device may be embedded in a substrate with its interface die located at the top of the substrate. In some of these embodiments, a compute die may also be embedded in the substrate and connected to the multi-stack memory device through an RDL on top of the substrate. In such an embodiment, a thermal structure may be located above the substrate to provide relatively direct thermal dissipation for the multi-stack memory device and/or the compute die. Depending on the implementation details, this may improve thermal dissipation, for example, because a relatively large portion of power dissipated by the multi-stack memory device may come from the interface die.

Some additional aspects of the disclosure relate to component assemblies having multi-stack memory devices and/or compute dies on both sides of one or more substrates which may include one or more embedded components. For example, in some embodiments, a first multi-stack memory device and a first compute die may be located on top of a substrate and connected through one or more bridges embedded in the substrate and/or an RDL on top of the substrate. A second multi-stack memory device and a first compute die may be located on the bottom of the substrate and connected through the one or more bridges embedded in the substrate and/or an RDL on the bottom of the substrate. Depending on the implementation details, this configuration may provide any of the features, benefits, and/or the like, described above with respect to embodiments having components located on one side of a substrate. Moreover, locating components on both sides of a substrate may enable the fabrication of assemblies having more multi-stack memory devices, compute dies, and/or the like, in a package.

Some embodiments may include two or more substrates, any or all of which may include one or more embedded components. Depending on the implementation details, this may provide multiple layers of embedded components such as multi-stack memory devices, compute dies, power conditioning devices (e.g., capacitors, voltage regulation modules, and/or the like), connecting elements (e.g., bridges), and/or the like or combinations thereof.

For example, some embodiments having two substrates may be implemented as two instances of a substrate having components on a single side stacked back to back, thus providing twice the device density in a package having the same or a similar footprint.

In any of the embodiments disclosed herein, one or more multi-stack memory devices may be implemented with a backside power delivery network (BSPDN) as described above.

In any of the embodiments disclosed herein, one or more thermal structures such as thermal vias, thermal lids, liquid cooling channels, and/or the like, may be included which, depending on the implementation details, may improve thermal performance.

In any of the embodiments disclosed herein, one or more substrates may be implemented with silicon (Si), glass, and/or the like, which, depending on the implementation details, may improve thermal performance, enable larger packages with more components, and/or the like.

In any of the embodiments disclosed herein, both sides of a substrate, assembly, package, and/or the like may provide, thermal dissipation, thereby improving thermal performance.

This disclosure encompasses numerous aspects relating to semiconductor packaging. The aspects disclosed herein may have independent utility and may be embodied individually, and not every embodiment may utilize every aspect. Moreover, the aspects may also be embodied in various combinations, some of which may amplify some benefits of the individual aspects in a synergistic manner.

For purposes of illustration, some embodiments may be described in the context of some specific implementation details such as device types, component placement, and/or the like. However, the aspects of the disclosure are not limited to these or any other implementation details. For example, some embodiments may be described in the context of stacked memory devices having two or more stacks of memory dies. However, the aspects of the disclosure may also be applied to embodiments in which a stacked memory device may have a single stack of memory dies. Moreover, although some example embodiments may be described in the context of stacks of memory dies and/or memory devices, some of the aspects may be applicable to other types of dies, devices, and/or the like.

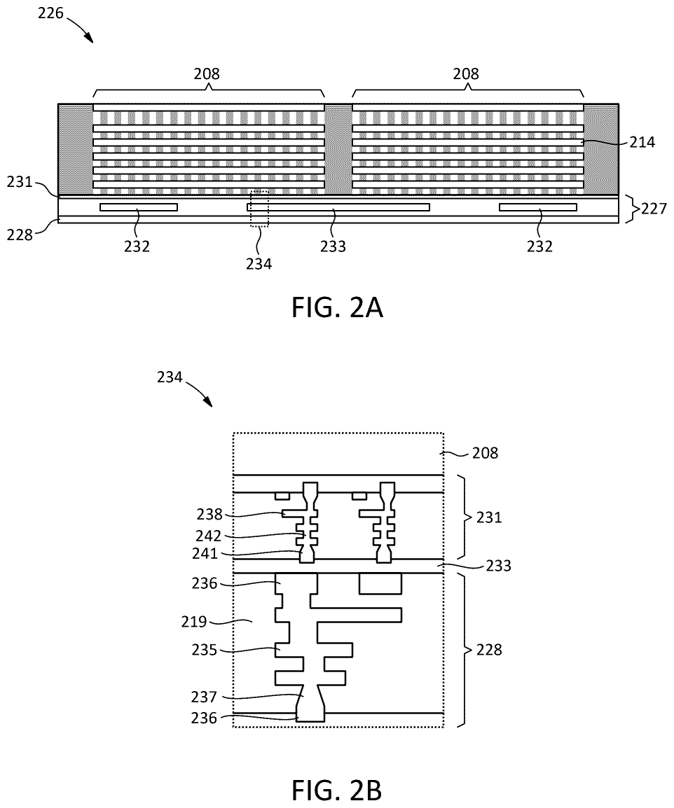

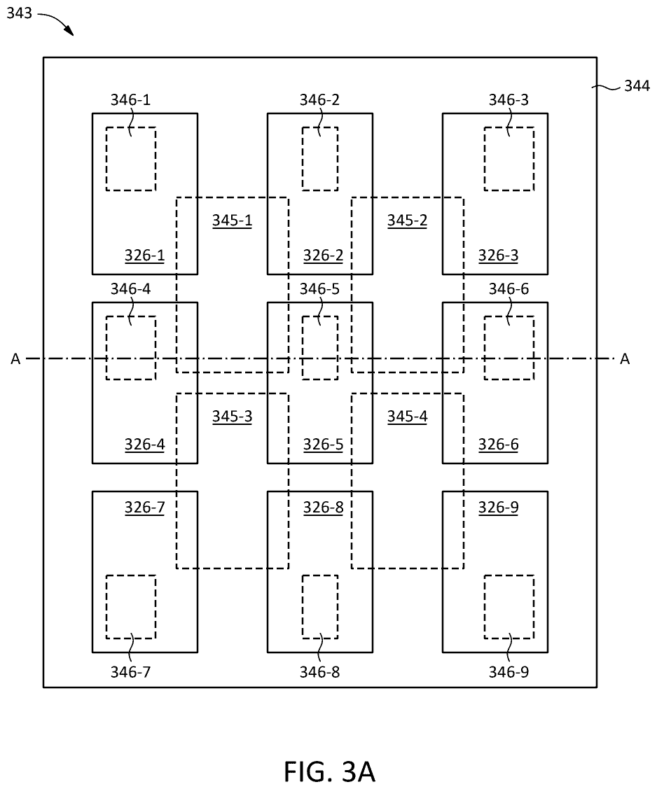

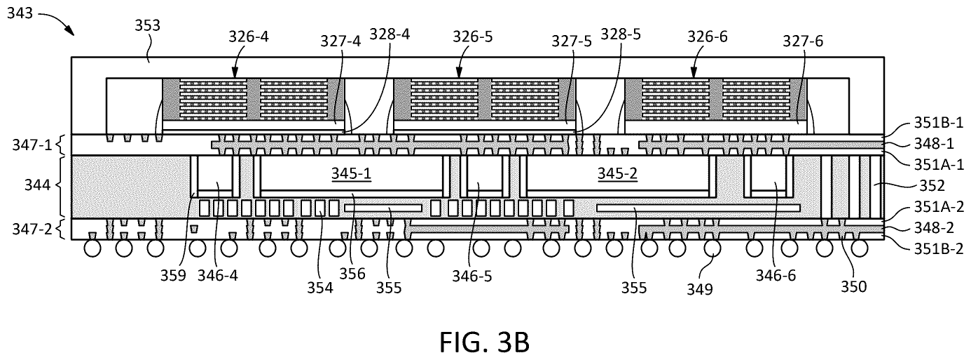

In some example embodiments described here, reference indicators having a base portion and a suffix portion may be referred to collectively and/or individually by the base portion. For example, referring to FIG. 3B, redistribution layers 347-1 and/or 347-2 may be referred to collectively and/or individually as 347. Similarly, multiple figures having the same numbers with different letter suffixes may be referred to collectively and/or individually by the number. For example, FIGS. 2A and 2B may be referred to collectively and/or individually as FIG. 2.

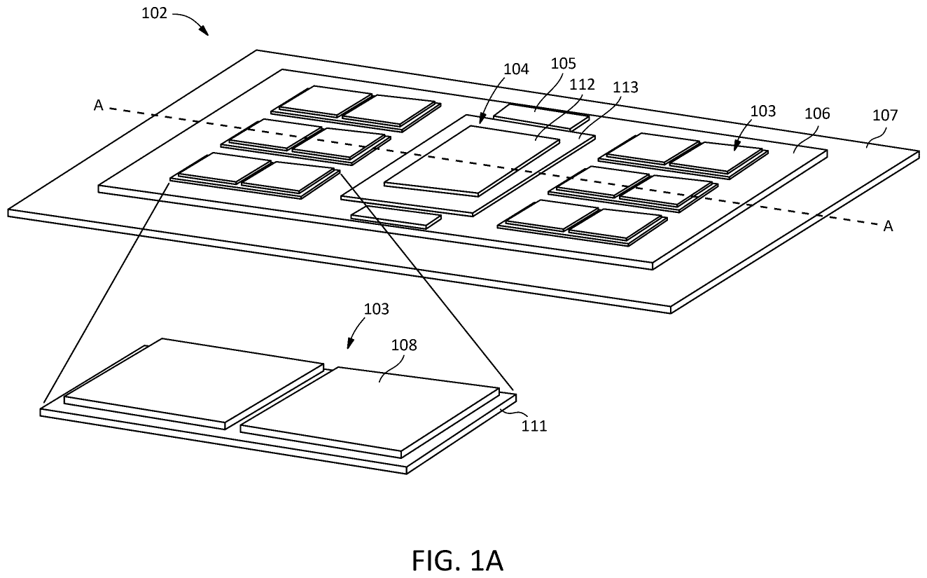

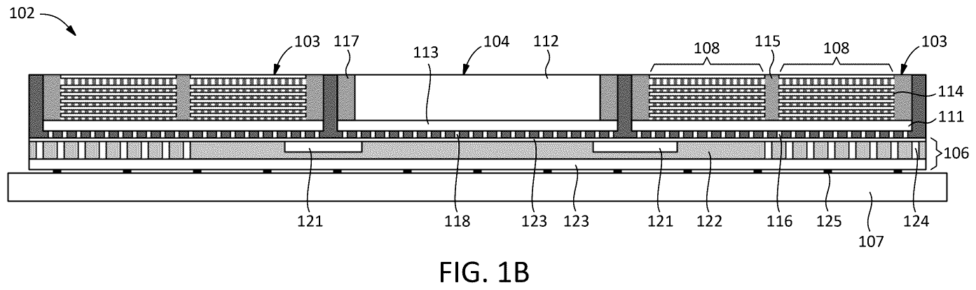

FIG. 1A illustrates an embodiment of a package architecture including a multi-stack memory device in accordance with example embodiments of the disclosure. The package architecture 102 may include one or more multi-stack memory devices 103, one or more compute devices 104, and/or one or more input and/or output (I/O or IO) devices 105 arranged on an interposer 106 which may be attached to a substrate 107.

A multi-stack memory device 103 (which may also be referred to as a multi-stack memory module or a stacked memory device) may include two or more stacks 108 of memory dies arranged on an interface die 111 which may also be referred to as a base die. A compute device 104 may include one or more compute dies 112 arranged on a base die 113.

FIG. 1B illustrates a cross-section taken through dot-dashed line A-A of the package architecture in FIG. 1A. A multi-stack memory device 103 may include two or more stacks 108 of memory dies 114 arranged on an interface die 111. A multi-stack memory device 103 may also include molding 115 that may surround, protect, and/or the like, the memory dies 114. The memory dies 114 may be implemented with any suitable memory devices such as dynamic random access memory (DRAM) devices. The memory dies 114 in a stack 108 may be connected (e.g., mechanically, electrically, thermally, and/or the like) to each other and/or the interface die 111, for example, using micro bumps, through silicon vias (TSVs), and/or the like. In some embodiments, a stack 108 of memory dies may be implemented with high bandwidth memory (HBM).

One or more (e.g., each) of the memory dies 114 may include any number of memory devices (e.g., memory integrated circuits (ICs) which may also be referred to as memory chips or chiplets) such as DRAM chips. For example, in some embodiments, each memory die 114 may include a single DRAM chip such that a stack 103 of memory dies 114 may essentially be a stack of DRAM chips (which may be referred to as a tower), In some other embodiments, each of the memory dies 114 may include two or more DRAM chips that may form two or more stacks or towers of DRAM chips.

An interface die 111 may include buffer circuitry to access the memory dies 114 and/or logic circuitry to perform one or more functions such as computations and/or any other processing functions. In some embodiments, logic circuitry in an interface die 111 may include custom circuitry to perform one or more functions that may be specified, for example, by a customer.

A multi-stack memory device 103 may be connected (e.g., mechanically, electrically, thermally, and/or the like) to the interposer 106, for example, using micro bumps 116 and/or any other connection techniques.

A compute device 104 may include one or more compute dies 112 that may be implemented for example, with one or more processors (e.g., central processing units (CPUs), graphics processing units (GPUs), neural processing units (NPUs), tensor processing units (TPUs), and/or the like), application specific integrated circuits (ASICs), field programmable gate arrays (FPGAs), complex programmable logic devices (CPLDs), and/or the like. The one or more compute dies 112 may be connected (e.g., mechanically, electrically, thermally, and/or the like) to the base die 113, for example, using bonding, micro bumps, and/or any other connection techniques. A compute device 104 may also include molding 117 that may surround, protect, and/or the like, the compute dies 112. A compute device 104 may be connected (e.g., mechanically, electrically, thermally, and/or the like) to the interposer 106, for example, using micro bumps 118 and/or any other connection techniques.

The interposer 106 may include one or more connecting elements 121 such as silicon bridges that may provide connections between the multi-stack memory devices 103, compute devices 104, IO devices, and/or the like. A connecting element 121 may be formed in or on a substrate 122. The interposer 106 may also include one or more redistribution layers 123 (e.g., at the top and/or bottom of the substrate 122) to provide connections between various components within the package architecture 102. The interposer 106 may also include one or more vias 124 (e.g., TSVs, through glass vias (TGVs), through organic vias (TOVs), and/or the like) to provide connections between the top and bottom of the substrate 122. The interposer 106 may be connected (e.g., mechanically, electrically, thermally, and/or the like) to the substrate 107, for example, using one or more solder connections 125.

In some embodiments, an interposer may provide one or more signal paths between components such as integrated circuits, stacks of integrated circuits, and/or the like, that may be connected to the interposer. Additionally, or alternatively, an interposer may provide one or more signal paths between a substrate connected to the interposer and one or more components such as integrated circuits, stacks of integrated circuits, and/or the like, that may be connected to the interposer. In some embodiments, an interposer may provide one or more signal paths in the form of conductive traces (e.g., within one or more RDLs), vias, bridges, and/or the like. Depending on the implementation details, an interposer may enable integrated circuits (e.g., chips or chiplets) to be interconnected to form a larger device or system. In some embodiments, an interposer may include a substrate, chip, and/or the like, formed from one or more semiconductors, organic materials, glass, and/or the like.

In some embodiments, a bridge may include a substrate, die, and/or other material having one or more conductive pathways that may form one or more connections between one or more semiconductor devices, substrates, interposers, or other package structures coupled to the bridge. In some embodiments, a bridge may include one or more traces, the traces forming a connection pathway along the bridge between one or more devices coupled to the bridge. In some embodiments, a bridge may be located at least partially on and/or at least partially within (e.g., embedded within) an interposer, substrate, and/or the like.

The package architecture 102 illustrated in FIG. 1A and FIG. 1B may enable faster memory access with higher bandwidth, larger storage capacity, and/or lower power consumption, for example, by enabling memory dies used for cache, static random access memory (SRAM), HBM, and/or the like, to may be placed relatively close to compute dies, by improving memory access by connecting components with semiconductor bridges, and/or by enabling a variety of different types of dies (which may also be referred to as chiplets) to be integrated into a package. However, it may be difficult to add additional compute devices 104, compute dies 112, multi-stack memory devices 103, memory dies 114, and/or the like, to the package architecture 102 because, for example, additional multi-stack memory devices 103 attached to the interposer 106 may be further from the compute device 104, thereby resulting in communication delays, increased power dissipation, and/or the like.

The multi-stack memory device 103 as described above may enable a relatively large number of memory dies to be fabricated in a compact assembly with a relatively large amount of interface circuitry (e.g., in an interface die). However, providing stable, reliable power to the components in such an assembly may be difficult because, for example, they may consume a relatively large amount of power through a power delivery network that may be routed in a complex arrangement with signal layers in the interface die.

FIG. 2A illustrates a cross-sectional view of an embodiment of a multi-stack memory device having a power delivery network in accordance with example embodiments of the disclosure. The multi-stack memory device 226 may include two or more stacks 208 of memory dies 214 connected to a first side of an interface die 227. The interface die 227 may include a power delivery network 228 on a second side of the interface die 227. One or more signal layers 231 may be located on the first side of interface die 227.

The interface die 227 may include one or more buffer circuits 232 to provide access (e.g., read access, write access, and/or the like) to the memory dies 214. Additionally, or alternatively, the interface die 227 may include one or more logic circuits (e.g., processing circuits such as CPUs, GPUs, NPUs, TPUs, and/or the like) 233 to perform operations on data stored in, and/or destined for, the memory dies 214. Additionally, or alternatively, the one or more logic circuits 233 may perform operations offloaded by other processing circuits (e.g., in other multi-stack memory devices, compute dies, and/or the like), using data stored in and/or destined for the memory dies 214, and/or data transferred to the interface die 227 for the offloaded operations.

In some embodiments, the one or more signal layers 231 may be completely, mostly, or at least partially separated from the power delivery network 228. Depending on the implementation details, this may improve the performance of a power delivery network 228, for example, by reducing routing congestion with one or more signal layers. Moreover, in some embodiments, locating some or all of a power delivery network 228 on the side of an interface die 227 attached to an interposer or substrate having one or more power conditioning devices (e.g., capacitors, voltage regulators, and/or the like as described in more detail below) may enable the power delivery network 228 to be located closer to the one or more power conditioning devices, thereby further improving the performance of the power delivery network 228.

Additionally, or alternatively, locating the one or more signal layers 231 completely, mostly, or at least partially separated from the power delivery network 228 may enable one or more stacks 208 of memory dies 214 to more closely (e.g., directly) connected (e.g., bonded) to one or more signal layers 231 of the interface die 227, thereby increasing bandwidth, reducing delay, and/or the like.

In some embodiments, a power delivery network 228 located completely, mostly, or at least partially on a side of an interface die 227 opposite one or more signal layers 231 may be referred to, and/or characterized as, a backside power delivery network (BSPDN). For example, in some embodiments, the power delivery network 228 may be fabricated in a back end of line (BEOL) process. In some embodiments, the side of interface die 227 may be referred to as a front or top side, and the side may be referred to as a back or bottom side.

FIG. 2B illustrates an enlarged view of a portion of the cross-sectional view of the embodiment of a multi-stack memory device illustrated in FIG. 2A. Referring to FIG. 2B, the portion 234 may include portions of a stack 208 of memory dies, one or more signal layers 231, a logic (e.g., processing) circuit 233, and/or a power delivery network 228.

The power delivery network 228 may include one or more layers of conductive traces 235 formed in a dielectric material 219 that may be formed in one or more layers. The power delivery network 228 may also include pads 236 and/or vias 237 to make connections with, and/or transfer power using, the one or more layers of conductive traces 235. The one or more signal layers 231 may include one or more layers of conductive traces 238. The one or more signal layers 231 may also include pads 241 and/or vias 242 to make connections with, and/or transfer signals using, the one or more layers of conductive traces 235. Any of all of conductive traces 235 and/or 238, pads 236 and/or 241, and/or vias 237 and/or 242 may be fabricated, for example, with any suitable conductive material(s) including metals such as copper, aluminum, and/or alloys thereof.

The logic (e.g., processing) circuit 233 may include one or more layers of transistors and/or other active and/or passive semiconductor devices that may implement a logic circuit 233, a buffer circuit 232, and/or the like.

Although the multi-stack memory device 226 illustrated in FIG. 2 may be shown as having two stacks 208 of memory dies 214, any number of stacks 208 may be used, e.g., 1, 2, 3, 4, or more stacks or towers of memory dies 214.

FIG. 3A illustrates a plan view of an embodiment of a package architecture including one or more multi-stack memory devices and a substrate with one or more embedded components in accordance with example embodiments of the disclosure. The package architecture 343 may include one or more multi-stack memory devices 326 located on a top side of a substrate 344 and one or more devices 345 mounted within one or more attachment locations (e.g., cavities) within the substrate 344 as indicated by the dashed outlines. The one or more devices 345 may be implemented, for example, with one or more bridges, compute devices, and/or the like, or a combination thereof.

In some embodiments, a device 345 may function as a connecting element (e.g., bridge) between two or more multi-stack memory devices 326, and thus, a device 345 may be located at least partially under two or more multi-stack memory devices 326. For example, device 345-1 may be located at least partially under one or more of multi-stack memory devices 326-1, 326-2, 326-4, and/or 326-5. In some embodiments, a device 345 may function as both a connecting element and a compute device.

The package architecture 343 may also include one or more power conditioning devices 346 located within one or more attachment locations (e.g., cavities) within the substrate 344 as indicated by the dashed outline. Examples of power conditioning devices 346 may include capacitors (e.g., integrated stack capacitors (ISCs)), voltage regulators (e.g., voltage regulator modules (VRMs)), and/or the like. In some embodiments, a power conditioning device 346 may be located close to (e.g., adjacent to, and/or at least partially directly under) a component such as a multi-stack memory device 326 and/or compute device 345 for which it may provide power conditioning.

FIG. 3B illustrates a cross-sectional view of the package architecture illustrated in FIG. 3A taken through dot-dashed line A-A in accordance with example embodiments of the disclosure. Referring to FIG. 3B, the package architecture 343 may include a substrate 344 having a first RDL 347-1 formed on a first side (e.g., top or front side) and a second RDL 347-2 formed on a second side (e.g., bottom or back side). In some embodiments, and depending on context, one or more of the RDLs 347 may be referred to and/or characterized as being part of the substrate 344, and/or the substrate 344 may be referred to and/or characterized as a substrate core. For purposes of illustration, an RDL 347 may be shown with a single layer of conductive traces 348 and top and bottom layers of vias 350 formed in layers of dielectric material 351 and/or other connecting structures, but RDLs with any number of layers may be used. An RDL may also be referred to as a distribution layer.

In some embodiments, an RDL may be implemented with one or more layers of dielectric and one or more layers of conductors. For example, an RDL may include a first layer of dielectric material 351A that may function as a substrate or base for the RDL structure. A layer 348 of conductive traces (e.g., using metal such as copper, aluminum, and/or the like) may be formed (e.g., using one or more deposition and/or patterning techniques) on the dielectric layer 351A to create a network of electrical connections. One or more additional layers of dielectric material 351B and/or conductive material may be formed over the first dielectric layer and/or the first conductive layer 348 depending on the number and/or complexity of connections to be used in the RDL. An RDL may further include one or more layers of vias and/or other connecting structures that may connect conductive traces on one layer with conductive traces on another layer and/or with one or more pads or other structures and/or devices such as dies, modules, and/or the like, connected to the RDL.

The package architecture 343 may also include one or more multi-stack memory devices 326 such as those described with respect to FIGS. 1 and 2 attached to the first RDL 347-1 on the first side of the substrate 344. One or more of the multi-stack memory devices 326 may include an interface die 327 with a power delivery network that may be at least partially separate from one or more signal layers. For example, multi-stack memory devices 326-4 and/or 326-5 may include BSPDNs 328-4 and/or 328-5, respectively.

The package architecture 343 may also include one or more components embedded in the substrate 344. For example, devices 345, which may be implemented with one or more bridges, compute dies, and/or the like, or a combination thereof, may be mounted within one or more attachment locations (e.g., cavities) within the substrate 344. In some embodiments, a device 345 may function as both a connecting element and a compute device.

One or more of the components embedded in the substrate 344 may be connected to one or more other components embedded in the substrate 344 and/or located on the substrate 344 (e.g., one or more multi-stack memory devices 326) through the first RDL 347-1. The first RDL 347-1 may also connect one or more of the multi-stack memory devices 326 to one or more other multi-stack memory devices 326 (and/or other components located on the first RDL 347-1).

In some embodiments, a device 345 may function as a connecting element (e.g., semiconductor bridge) between two or more multi-stack memory devices 326. In some embodiments, a device 345 may function as an active bridge, for example, if the device 345 is implemented with a compute die or other device having transistors and/or other active semiconductor devices. Depending on the implementation details, this may increase the density of connections between two or more multi-stack memory devices 326 and/or other components located on the top side of the substrate 344 and/or the first RDL 347-1.

In some embodiments in which one or more devices 345 may function as connecting elements, at least a portion of a device 345 may be located at least partially under (e.g., directly under) one or more of the components it may connect. For example, device 345-2 may be located partially beneath multi-stack memory devices 326-5 and 326-6. This may provide a vertical die to die connection between device 345-2 and multi-stack memory device 326-5 and/or between device 345-2 and multi-stack memory device 326-6 which, depending on the implementation details, may reduce the length of the connections, increase bandwidth, reduce delay, reduce power consumption, increase device packaging density (e.g., by accommodating more multi-stack memory devices 326 and/or devices 345), and/or the like. Even if no portion of a device 345 may be located directly under any portion of a multi-stack memory device 326 or other component attached to the top of the substrate 344, it may still improve one or more connections between such components, for example, by being located relatively close to such components.

Additionally, or alternatively, the package architecture 343 may include one or more power conditioning devices 346 such as ISCs, VRMs, and/or the like, located within one or more attachment locations (e.g., cavities) within the substrate 344. In some embodiments, a power conditioning device 346 may be located close to (e.g., adjacent to, and/or at least partially directly under) a component such as a multi-stack memory device 326 and/or compute device 345 for which it may provide power conditioning. Depending on the implementation details, this may improve the performance of a power delivery network at a multi-stack memory device 326 (e.g., a BSPDN 327), compute device 345, and/or the like.

The substrate 344 may include one or more vias 352 such as TSVs, TOVs, and/or other connection structures to connect the first RDL 347-1 to the second RDL 347-2 and/or to one or more connections (e.g., solder connections such as solder balls) 349 to enable the package architecture 343 to be connected to a circuit board or other component.

Additionally, or alternatively, one or more thermal structures may be included to facilitate thermal dissipation at the top and/or bottom sides of the package architecture 343. For example, in some embodiments, a thermally conductive lid (e.g., copper, aluminum, and/or the like) 353 may be attached to one or more multi-stack memory devices 326 and/or the substrate 344 (e.g., using a thermal interface material (TIM)) to provide thermal dissipation at the top side of the package architecture 343. Additionally, or alternatively, one or more thermal vias 354 and/or cooling channels (e.g., liquid cooling channels, microchannels, and/or the like) 355 may be embedded in the substrate 344 to provide thermal dissipation at the bottom side of the package architecture 343.

The substrate 344 may be implemented with any suitable material such as organic materials, glass, semiconductor (e.g., silicon), and/or the like, or a combination thereof. In some embodiments, the use of a glass and/or silicon for a substrate may enable a larger overall package size for the package architecture 343 due to the mechanical and/or other properties of glass and/or silicon. Examples of properties of glass and/or silicon that may be beneficial may include any number of the following. Glass and/or silicon may be relatively rigid which may enable the fabrication of larger substrates. Glass and/or silicon substrates may be fabricated with relatively flat surfaces which may enable denser line spacing (e.g., smaller traces). For example, in some embodiments, and depending on the implementation details, line spacing (L/S) of 9/12 (e.g., 9 micrometer (micron or μm) line width and 12 micron spacing between lines) may be readily achieved on an organic substrate, and L/S dimensions of 5 microns may be achieved with difficulty. In contrast, L/S dimensions of 2 microns and even sub-micron dimensions may be achieved with glass and/or silicon substrates. Glass and/or silicon substrates may have a coefficient of thermal expansion (CTE) that may be closer to a semiconductor (e.g., Si) die. For example, in some embodiments, and depending on the implementation details, an organic substrate may have a Cry of about 20, whereas a next generation substrate material such as glass and/or silicon may have a Cre of about 2. In some embodiments, and depending on the implementation details, glass and/or silicon substrates may provide better control of warpage compared to organic substrates. In some embodiments, and depending on the implementation details, glass and/or silicon substrates may provide better thermal dissipation compared to organic substrates.

Although the embedded components illustrated in FIG. 3B may be shown in cavities located on one side of the substrate 344, in some other embodiments, a substrate 344 may have components embedded in cavities on both sides.

The one or more multi-stack memory devices 326 may be joined to the substrate 344 and/or first RDL 347-1 using any suitable joining techniques such as micro bumps (e.g., solder), bonding (e.g., hybrid bonding), TSVs, and/or the like. The one or more devices 345 may also be joined to the substrate 344 using, for example, one or more backside films 356. One or more gaps 359, if any, between the one or more devices 345 and the substrate 344 may be filled, for example, using one or more build-up films (e.g., Ajinomoto build-up film (ABF)), RDL lamination (e.g., polyimide), and/or other materials.

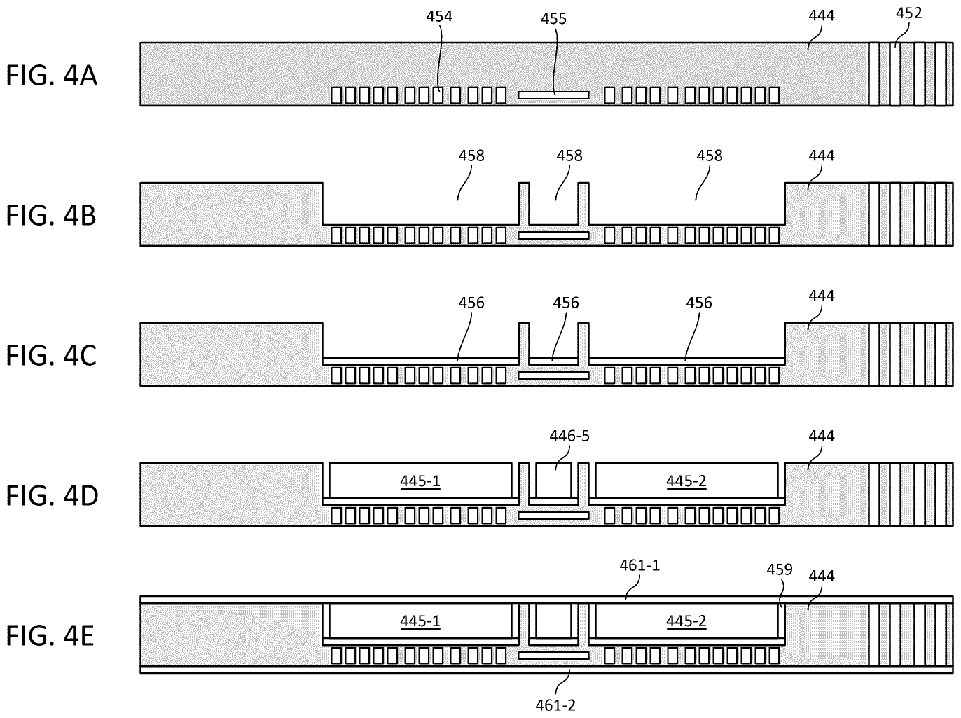

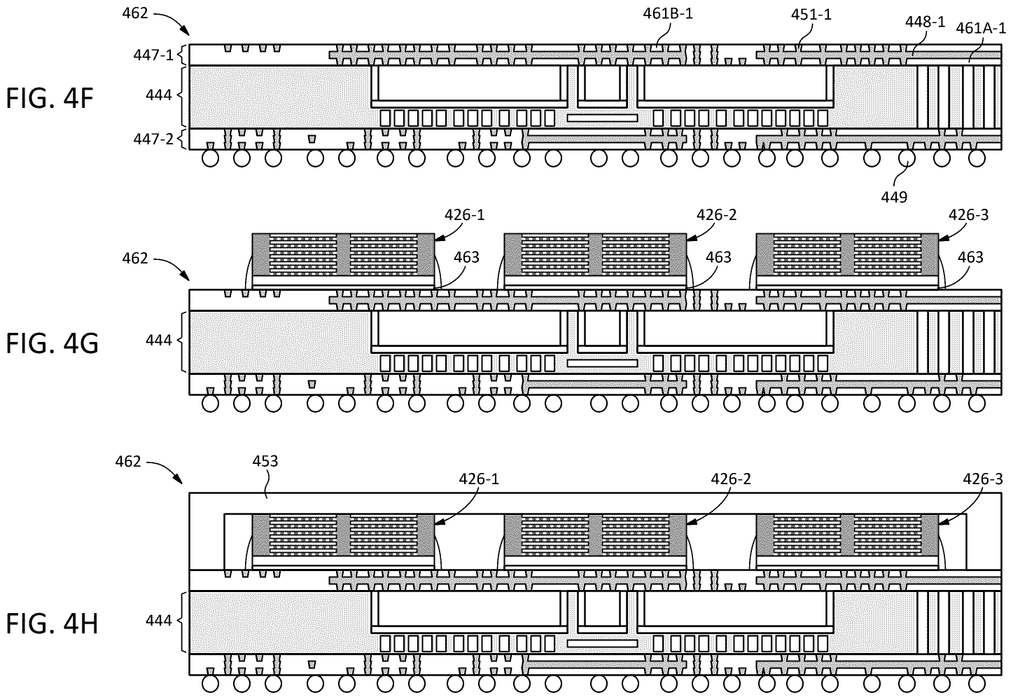

FIGS. 4A through 4H illustrate cross-sectional views of an embodiment of a method for fabricating a package architecture including one or more multi-stack memory devices and a substrate with one or more embedded components in accordance with example embodiments of the disclosure. The method illustrated in FIGS. 4A through 4H may be used, for example, to fabricate the embodiment illustrated in FIG. 3 and/or any other embodiments disclosed herein. The operations and/or structures illustrated in, and described with respect to, FIGS. 4A through 4H are example operations and/or components shown in a sequence for purposes of illustration. However, in some embodiments, some operations and/or components may be omitted and/or other operations and/or components may be included. Moreover, in some embodiments, the temporal and/or spatial order of the operations and/or components may be varied. Although some components and/or operations may be illustrated as individual components, in some embodiments, some components and/or operations shown separately may be integrated into single components and/or operations, and/or some components and/or operations shown as single components and/or operations may be implemented with multiple components and/or operations.

Referring to FIG. 4A, one or more thermal vias 454, liquid cooling channels 455, and/or electrical vias (e.g., TSV, TGV, TOV, and/or the like) 452 may be formed in a substrate 444 using any suitable fabrication processes, for example, at a wafer level, panel level, and/or the like.

Referring to FIG. 4B, one or more cavities 458 for one or more embedded components may be formed in the substrate 444 using any suitable process such as laser milling, wet etching, and/or the like, within a wafer, panel, and/or the like implemented with glass, silicon, and/or any other substrate material or combination thereof.

Referring to FIG. 4C, one or more die backside films 456 may be formed in one or more cavities 458.

Referring to FIG. 4D, one or more embedded components (e.g., power conditioning devices 446, compute dies and/or connecting elements 445, and/or the like) may be positioned at least partially within one or more cavities 458 and attached to the one or more die backside films 456.

Referring to FIG. 4E, one or more layers of build-up film, RDL lamination (e.g., dielectric film), and/or the like may be formed on one or both sides of the substrate 444 to form a first layer 461 of one or more RDLs and/or to fill one or more gaps 459, if any, between one or more embedded components 445, 446 and the substrate 444.

Referring to FIG. 4F, one or more layers of conductive traces 448 may be formed on one or more first layers 461A of one or more RDLs. Additionally, or alternatively, one or more layers 461B of RDL lamination and/or build-up film may be formed and/or techniques such as lithography may be used to create, vias 451, bumps, and/or the like to form one or more RDLs 447. In some embodiments, one or more connections (e.g., solder connections such as solder balls) 449 may be formed on the bottom side of the substrate 444. In some embodiments, one or more substrate units 462 may be tested and/or singulated, for example, by dicing from a wafer, panel, and/or the like.

Referring to FIG. 4G, one or more multi-stack memory devices 426 (any number of which may include one or more BSPDNs) and/or other components such as single stack memory devices (e.g., HBM devices) may be attached to the top side of the substrate 444. In some embodiments, one or more materials such as molded underfill (MUF), epoxy molding compound (EMC), and/or the like, may be used for underfill 463 (e.g., at the level of units 462).

Referring to FIG. 4H, one or more thermal structures such as a thermally conductive lid (e.g., copper, aluminum, and/or the like) 453 may be attached to one or more multi-stack memory devices 426 and/or the substrate 444 (e.g., using a TIM) to provide thermal dissipation at the top side of the unit 462.

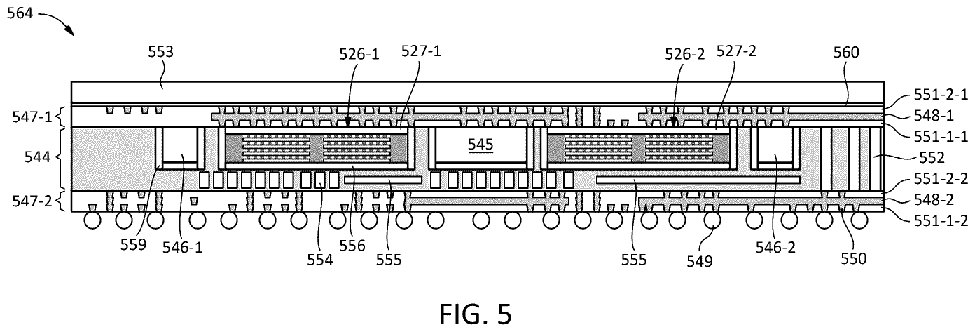

FIG. 5 illustrates an embodiment of a package architecture having a multi-stack memory device embedded in a substrate in accordance with example embodiments of the disclosure. The package architecture 564 illustrated in FIG. 5 may include one or more elements that may be similar to those illustrated in FIGS. 3 and/or 4, in which similar elements may be indicated by reference numbers ending in, and/or containing, the same digits, letters, and/or the like. However, in the embodiment illustrated in FIG. 5, one or more multi-stack memory devices 526 may be embedded in a substrate 544.

For example, in some embodiments, a multi-stack memory device 526 may be embedded in substrate 544 and oriented with an interface die 527 located at, and/or facing, the top side of the substrate 544. An interface die 527 of an embedded multi-stack memory device 526 may be connected to the same side of an RDL 547-1 as one or more other components embedded in the substrate 544 such as one or more compute dies 545, power conditioning devices 546, and/or the like. In some embodiments, one or more embedded multi-stack memory devices 526 may be connected (e.g., for communication) to one or more other embedded multi-stack memory devices 526, compute dies 545, power conditioning devices 546, and/or the like, using the RDL 547-1. In one example implementation, power conditioning device 546-1 may be implemented with an ISC, and power conditioning device 546-2 may be implemented with a VRM.

Depending on the implementation details, embedding a multi-stack memory device 526 in a substrate 544 may provide improved thermal dissipation. For example, in some embodiments, a relatively large portion of power dissipated by a multi-stack memory device 526 may come from the interface die 527. Thus, embedding a multi-stack memory device 526 in a substrate 544 and locating the interface die 527 at the top side of the substrate may enable the power dissipated by the interface die 527 to leave the package architecture 564 through a relatively short thermal path through the top side of the substrate 544. Moreover, the configuration illustrated in FIG. 5 may enable a thermal structure 553 such as a thermally conductive lid and/or liquid cooling lid to be attached to the substrate 544 (e.g., using a TIM 560) relatively close to the interface die 527 which may further improve thermal dissipation from the interface die 527.

In some embodiments, a multi-stack memory device 526 may be positioned at least partially within one or more cavities and/or attached to the substrate 544 using one or more die backside films 556 in a manner similar to that used for the embedded components 445 and/or 446 illustrated in FIG. 4D.

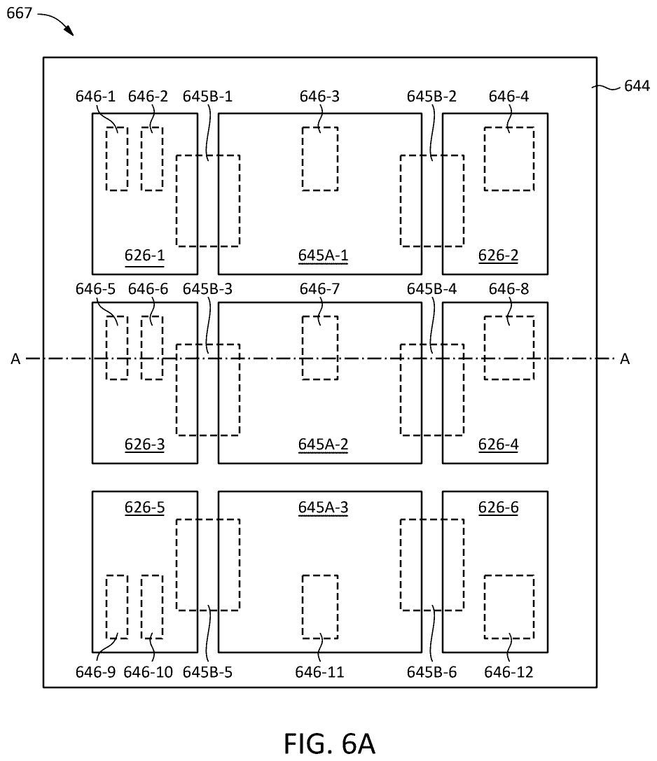

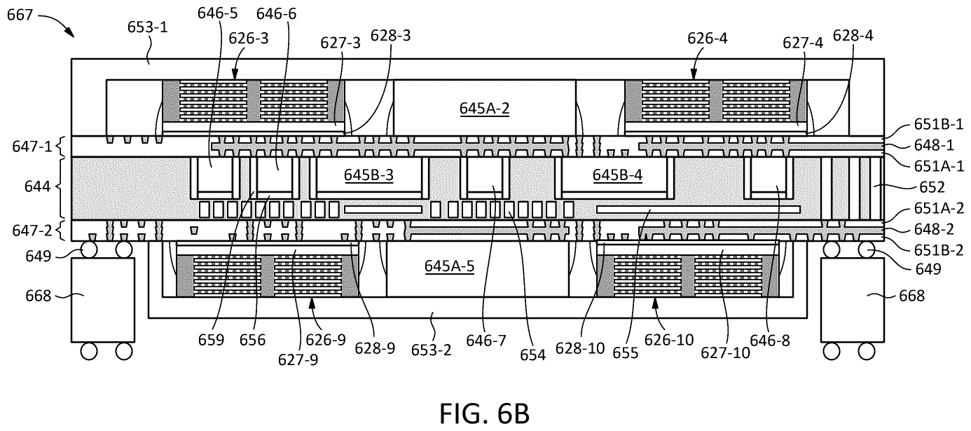

FIG. 6A illustrates a plan view of an embodiment of a package architecture including multi-stack memory devices on two sides of a substrate with one or more embedded components in accordance with example embodiments of the disclosure. The package architecture 667 may include components such as one or more multi-stack memory devices 626 and/or one or more compute dies 645A located on a top side of a substrate 644. The substrate 644 may include one or more embedded components located within an attachment location (e.g., a cavity) as indicated by the dashed lines including one or more connecting elements (e.g., bridges) 645B, one or more power conditioning devices (e.g., capacitors such as ISCs, voltage regulators such as VRMs, and/or the like) 646, and/or other embedded components such as compute dies, memory devices, and/or the like. In some embodiments, a power conditioning device 646 may be located close to (e.g., adjacent to, and/or at least partially directly under) a component such as a multi-stack memory devices 626 and/or compute device 645 for which it may provide power conditioning.

The one or more connecting elements (e.g., bridges) 645B may connect two or more multi-stack memory devices 626 and/or compute dies 645A, and thus, a connecting element 645B may be located at least partially under two or more components such as one or more multi-stack memory devices 626 and/or one or more compute dies 645A. For example, connecting element 645B-4 may be located at least partially under multi-stack memory device 626-4 and compute die 645A-2. In some embodiments, a connecting element 645B may function as both a connecting element and a compute device.

The package architecture 667 may further include one or more additional components such as one or more multi-stack memory devices 626 and/or one or more compute dies 645A located on a bottom side of the substrate 644. The one or more additional components located on the bottom side of substrate 644 may not be visible in the view illustrated in FIG. 6A because they may be aligned over similar components located on the top side of substrate 644, but in other embodiments, the top and/or bottom sides of the substrate 644 may have a different combination of components in different locations.

FIG. 6B illustrates a cross-sectional view of the package architecture illustrated in FIG. 6A taken through dot-dashed line A-A in accordance with example embodiments of the disclosure. The package architecture 667 illustrated in FIG. 6 may include one or more elements that may be similar to those illustrated in FIGS. 3, 4, and/or 5, in which similar elements may be indicated by reference numbers ending in, and/or containing, the same digits, letters, and/or the like.

Referring to FIG. 6B, the package architecture 667 may include a substrate 644 having a first RDL 647-1 formed on a first side (e.g., top or front side) and a second RDL 647-2 formed on a second side (e.g., bottom or back side). In some embodiments, and depending on context, one or more of the R.DLs 647 may be referred to and/or characterized as being part of the substrate 644, and/or the substrate 644 may be referred to and/or characterized as a substrate core. For purposes of illustration, the RDLs 647 may be shown with a single layer of conductive traces 648 and top and bottom layers of vias 651 and/or other connecting structures, but RDLs with any number of layers may be used. In some embodiments, an RDL may be implemented with one or more layers of dielectric and one or more layers of conductors as described above with respect to the embodiment illustrated in FIG. 3.

The package architecture 647 may also include one or more multi-stack memory devices 626 such as those described with respect to FIGS. 1 and 2 attached to the first RDL 647-1 on the first (e.g., top) side of the substrate 644. One or more of the multi-stack memory devices 626 may include an interface die 627 with a power delivery network that may be at least partially separate from one or more signal layers. For example, multi-stack memory devices 626-3 and/or 626-4 may include BSPDNs 628-3 and/or 628-4, respectively.

The package architecture 647 may also include one or more components embedded in the substrate 644, e.g., mounted within one or more attachment locations (e.g., cavities) within the substrate 644. Examples of embedded components may include connecting elements (e.g., bridges) 645B, power conditioning devices 646 (e.g., capacitors 646A, voltage regulators 646B, and/or the like), compute dies, and/or the like, or combinations thereof. Although the embedded components illustrated in FIG. 6B may be shown in cavities located on one side of the substrate 644, in some other embodiments, a substrate 644 may have cavities on both sides. In some embodiments, an embedded component (e.g., a bridge 645B) may function as both a connecting element and a compute device.

One or more of the components embedded in the substrate 644 may be connected to one or more other components embedded in the substrate 644 and/or located on the substrate 644 through the first RDL 647-1. The first RDL 647-1 may also connect one or more of the multi-stack memory devices 626 to one or more other multi-stack memory devices 626 (and/or other components located on the first RDL 647-1).

In some embodiments, a connecting element 645B (e.g., a semiconductor bridge) may connect one or more multi-stack memory devices 626, one or more compute dies 645A, and/or the like located on the top side of the substrate 644. In some embodiments, a connecting element 645B may function as an active bridge, for example, if the connecting element 645B is implemented with a device having transistors and/or other active semiconductor devices. Depending on the implementation details, this may increase the density of connections between one or more multi-stack memory devices 626, one or more compute dies 645A, and/or the like, located on the top side of the substrate 644 and/or the first RDL 647-1.

In some embodiments in which one or more embedded components (e.g., connecting devices 645B) may function as connecting elements, at least a portion of an embedded component may be located at least partially under (e.g., directly under) one or more of the components it may connect. For example, device connecting element 645B-4 may be located partially beneath compute die 645A-2 and multi-stack memory device 626-4. This may provide a vertical die to die connection between connecting element 645B-4 and compute die 645A-2 and/or between connecting element 645B-4 and multi-stack memory device 626-4 which, depending on the implementation details, may reduce the length of the connections, increase bandwidth, reduce delay, reduce power consumption, increase device packaging density (e.g., by accommodating more multi-stack memory devices 626 and/or compute dies 645A), and/or the like. Even if no portion of a connecting element 645B-4 may be located directly under any portion of a compute die 645A, multi-stack memory device 626, and/or other component attached to the top of the substrate 644, it may still improve one or more connections between such components, for example, by being located relatively close to such components.

In some embodiments, a power conditioning device 646 may be located close to (e.g., adjacent to, and/or at least partially directly under) a component such as a multi-stack memory device 626 and/or compute device 645A for which it may provide power conditioning. Depending on the implementation details, this may improve the performance of a power delivery network at a multi-stack memory device 626 (e.g., a BSPDN 627), compute device 645A, and/or the like. In one example embodiment, power conditioning devices 646-5 and/or 646-7 may be implemented with ISCs, and power conditioning devices 646-6 and/or 646-8 may be implemented with VRMs.

The package architecture 647 may also include one or more components such as one or more multi-stack memory device 626 and/or one or more compute devices 645A located on the second (e.g., bottom) side of the substrate 644 and/or the second RDL 647-2. One or more bottom side components (e.g., 626-9, 626-10, and/or 645A-5) may be connected (e.g., for communications) to each other through the second RDL 647-2. Additionally, or alternatively, the one or more bottom side components (e.g., 626-9, 626-10, and/or 645A-5) may be connected (e.g., for communications) to one or more top side components (e.g., 626-3, 626-4, and/or 645A-2) and/or one or more embedded components in the substrate 644 through the RDLs 647-1 and/or 647-2 and/or one or more vias 652 such as TSVs, TOVs, and/or other connection structures that may connect the first RDL 647-1 to the second RDL 647-2 and/or to one or more connections (e.g., solder connections such as solder balls) 649 to enable the package architecture 647 to be connected to a circuit board 668 or other component. In some embodiments, a circuit board 668 or other component may have an opening or cavity to accommodate the one or more bottom side components when the package architecture 647 is attached to the circuit board 668 or other component.

One or more of the multi-stack memory devices 626 located on the bottom side of the substrate 644 may include an interface die 627 with a power delivery network that may be at least partially separate from one or more signal layers. For example, multi-stack memory devices 626-9 and/or 626-10 may include BSPDNs 628-9 and/or 628-10, respectively.

Depending on the implementation details, locating components on both sides of the substrate 644 may increase the device density of the package architecture 647, for example, by enabling more devices to be included in the package architecture 647. Additionally, or alternatively, locating components on both sides of the substrate 644 may increase bandwidth, reduce delay, reduce power consumption, and/or the like, for example, by reducing the distance between components on the top side of the substrate 644 and components on the bottom side of the substrate which otherwise may be located outside of the package architecture 647.

The package architecture 647 may also include one or more thermal structures to facilitate thermal dissipation at the top and/or bottom sides of the package architecture 647. For example, in some embodiments, a first thermally conductive lid (e.g., copper, aluminum, and/or the like) 653-1 may be attached to one or more compute devices 645A, multi-stack memory devices 626, and/or the substrate 644 (e.g., using a thermal interface material (TIM)) to provide thermal dissipation at the top side of the package architecture 647. Additionally, or alternatively, a second thermally conductive lid (e.g., copper, aluminum, and/or the like) 653-2 may be attached to one or more compute devices 645A, multi-stack memory devices 626, and/or the substrate 644, to provide thermal dissipation at the bottom side of the package architecture 647.

Additionally, or alternatively, one or more thermal vias 654 and/or cooling channels (e.g., liquid cooling channels, microchannels, and/or the like) 655 may be embedded in the substrate 644 to provide thermal dissipation from the substrate 644 and/or one or more components embedded and/or attached thereto.

The substrate 644 may be implemented with any suitable material such as organic materials, glass, semiconductor (e.g., silicon), and/or the like, or a combination thereof as discussed above with respect to the embodiment illustrated in FIG. 3. The one or more compute dies 645A, multi-stack memory devices 626, and/or any other components may be joined to the substrate 644, first RDL 647-1, and/or second R.DL 647-2 using any suitable joining techniques such as micro bumps (e.g., solder), bonding (e.g., hybrid bonding), TSVs, and/or the like. The one or more devices 645 may also be joined to the substrate 644 using, for example, one or more backside films 656. One or more gaps 659, if any, between the one or more devices 645 and the substrate 644 may be filled, for example, using one or more build-up films, RDL lamination, and/or other materials.

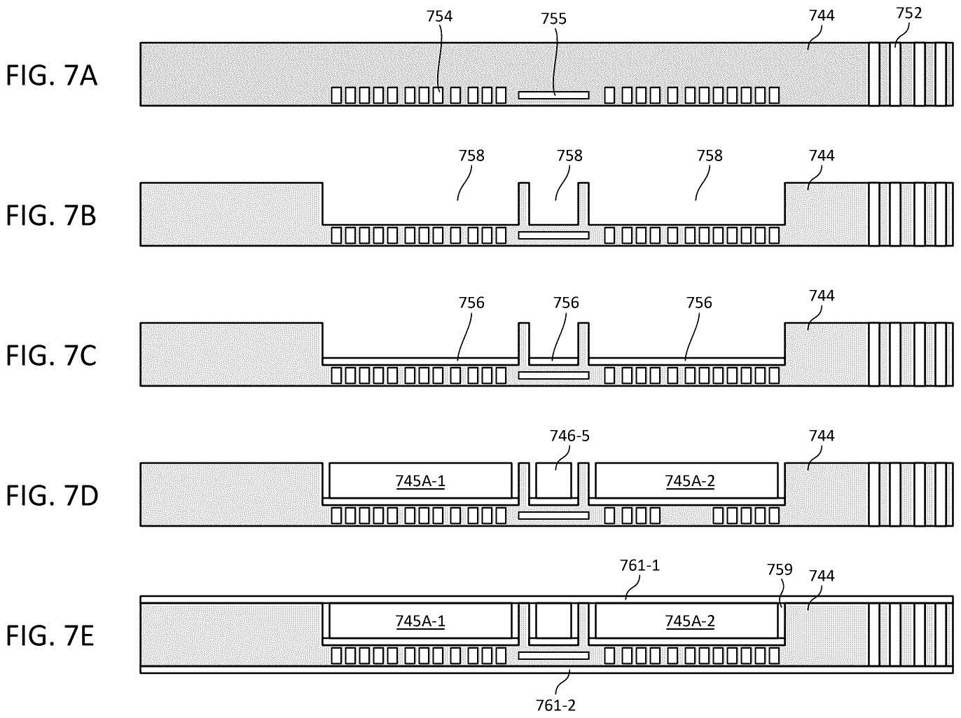

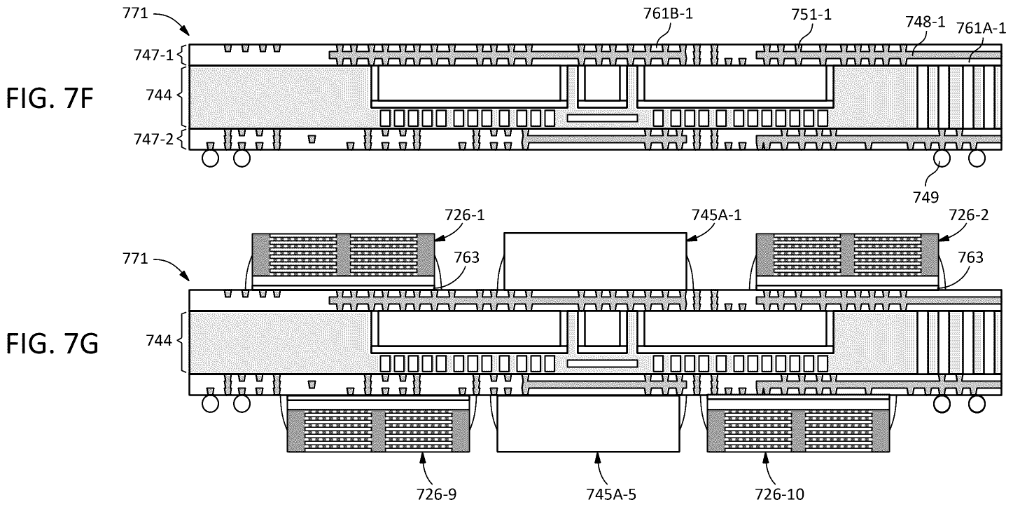

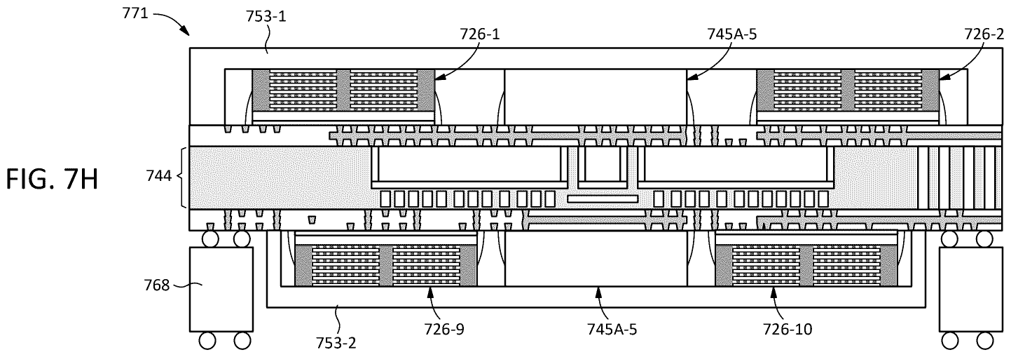

FIGS. 7A through 7H illustrate cross-sectional views of an embodiment of a method for fabricating a package architecture including one or more multi-stack memory devices and a substrate with one or more embedded components in accordance with example embodiments of the disclosure. The method illustrated in FIGS. 7A through 7H may be used, for example, to fabricate the embodiment illustrated in FIG. 6 and/or any other embodiments disclosed herein. The operations and/or structures illustrated in, and described with respect to, FIGS. 7A through 7H are example operations and/or components shown in a sequence for purposes of illustration. However, as with the embodiment illustrated in FIG. 4, in some embodiments, some operations and/or components may be omitted and/or other operations and/or components may be included, the order of operations may be changed, and/or operations may be combined and/or split into separate operations.

Referring to FIG. 7A, one or more thermal vias 754, liquid cooling channels 755, and/or connection vias (e.g., TSV, TGV, TOV, and/or the like) 752 may be formed in a substrate 744 using any suitable fabrication processes, for example, at a wafer level, panel level, and/or the like.

Referring to FIG. 7B, one or more cavities 758 for one or more embedded components may be formed in the substrate 744 using any suitable process such as laser milling, wet etching, and/or the like, within a wafer, panel, and/or the like implemented with glass, silicon, and/or any other substrate material or combination thereof.

Referring to FIG. 7C, one or more die backside films 756 may be formed in one or more cavities 758.

Referring to FIG. 7D, one or more embedded components (e.g., power conditioning devices 746, compute dies 745A, connecting elements, multi-stack memory devices, and/or the like) may be positioned at least partially within one or more cavities 758 and attached to the one or more die backside films 756.

Referring to FIG. 7E, one or more layers of build-up film, RDL lamination (e.g., dielectric film), and/or the like may be formed on one or both sides of the substrate 744 to form a first layer 761 of one or more RDLs and/or to fill one or more gaps 759, if any, between one or more embedded components 745, 746 and the substrate 744.

Referring to FIG. 7F, one or more layers of conductive traces 748 may be formed on one or more first layers 761 of one or more RDLs. Additionally, or alternatively, one or more layers of RDL lamination and/or build-up film may be formed and/or techniques such as lithography may be used to create vias 751, bumps, and/or the like to form one or more RDLs 747. In some embodiments, one or more connections (e.g., solder connections such as solder balls) 749 may be formed on the bottom side of the substrate 744. In some embodiments, one or more substrate units 771 may be tested and/or singulated, for example, by dicing from a wafer, panel, and/or the like.

Referring to FIG. 7G, one or more compute dies 745A, multi-stack memory devices 726 (any number of which may include one or more BSPDNs) and/or other components such as single stack memory devices (e.g., HBM devices) may be attached to the top side of the substrate 744. Additionally, or alternatively, one or more compute dies 745A, multi-stack memory devices 726 (any number of which may include one or more BSPDNs) and/or other components such as single stack memory devices (e.g., HBM devices) may be attached to the bottom side of the substrate 744. In some embodiments, one or more components may be attached to the top side of the substrate 744 before attaching one or more components to the bottom side of the substrate 744. In some embodiments, one or more materials such as molded underfill (MUF), epoxy molding compound (EMC), and/or the like may be used for underfill 763 (e.g., at the level of units 771).

Referring to FIG. 7H, one or more thermal structures such as a thermally conductive lid (e.g., copper, aluminum, and/or the like) 753-1 may be attached to one or more compute dies 745A, one or more multi-stack memory devices 726, and/or the substrate 744 (e.g., using a TIM) to provide thermal dissipation at the top side of the unit 771. Additionally, or alternatively, one or more thermal structures such as a thermally conductive lid 753-2 may be attached to one or more compute dies 745A, one or more multi-stack memory devices 726, and/or the substrate 744 to provide thermal dissipation at the bottom side of the unit 771. The package architecture 747 may be attached, for example, to a circuit board, organic substrate, and/or the like, 768 using one or more connections (e.g., solder connections such as solder balls) 749.

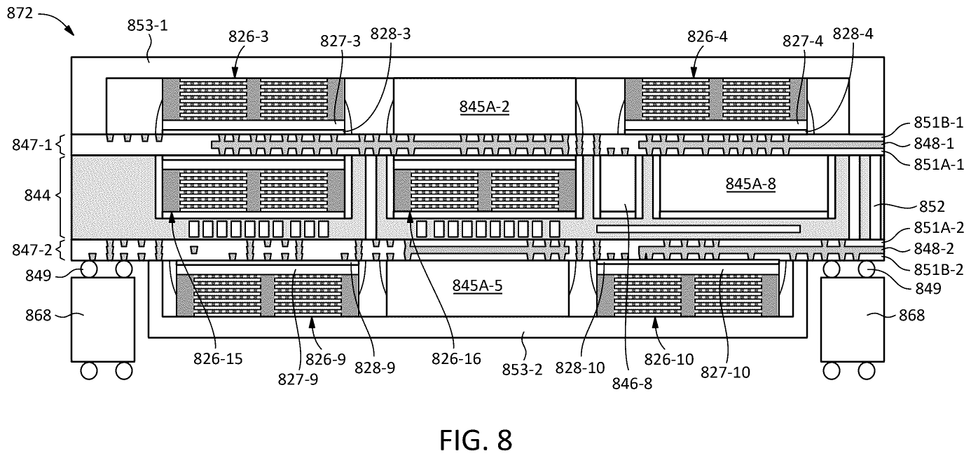

FIG. 8 illustrates an embodiment of a package architecture having components on two sides of a substrate and a multi-stack memory device embedded in the substrate in accordance with example embodiments of the disclosure. The package architecture 872 illustrated in FIG. 8 may include one or more elements that may be similar to those illustrated in FIGS. 6 and/or 7, in which similar elements may be indicated by reference numbers ending in, and/or containing, the same digits, letters, and/or the like. However, in the embodiment illustrated in FIG. 8, one or more multi-stack memory devices 826 may be embedded in a substrate 844.

For example, in some embodiments, a multi-stack memory device 826 may be embedded in substrate 844 and oriented with an interface die 827 located at, and/or facing, the top side of the substrate 844. An interface die 827 of an embedded multi-stack memory device 826 may be connected to the same side of an RDL 847-1 as one or more other components embedded in the substrate 844 such as one or more compute dies 845A, power conditioning devices 846, and/or the like. In some embodiments, one or more embedded multi-stack memory devices 826 may be connected (e.g., for communication) to one or more other components (e.g., multi-stack memory devices 826, compute dies 845A, power conditioning devices 846, and/or the like) that may be embedded in, and/or located on top of, the substrate 844 using the RDL 847-1. Additionally, or alternatively, one or more embedded multi-stack memory devices 826 may be connected (e.g., for communication) to one or more other components located at the bottom of the substrate 844 using one or both of the RDLs 847 and/or one or more vias 852 through the substrate 844.

The package architecture 872 may also include one or more thermal structures such as thermally conductive lids 853-1 and/or 853-2 to facilitate thermal dissipation at the top and/or bottom sides of the package architecture 872.

Depending on the implementation details, embedding a multi-stack memory device 826 in a substrate 844 may provide improved thermal dissipation in a manner similar to the embodiment illustrated in FIG. 6. Additionally, or alternatively, embedding a multi-stack memory device 826 in a substrate 844 may reduce the length of some connections, increase bandwidth, reduce delay, reduce power consumption, increase device packaging density (e.g., by accommodating more multi-stack memory devices 826) and/or the like.

In some embodiments, a multi-stack memory device 826 may be positioned at least partially within one or more cavities and/or attached to the substrate 844 using one or more die backside films in a manner similar to that used for the embedded components 745A and/or 746 illustrated in FIG. 7D. Although the embedded components illustrated in FIG. 8 may be shown in cavities located on one side of the substrate 844, in some other embodiments, a substrate 844 may have components embedded in cavities on both sides. In some embodiments, an embedded component (e.g., a compute die 845A) may function as both a connecting element and a compute device.

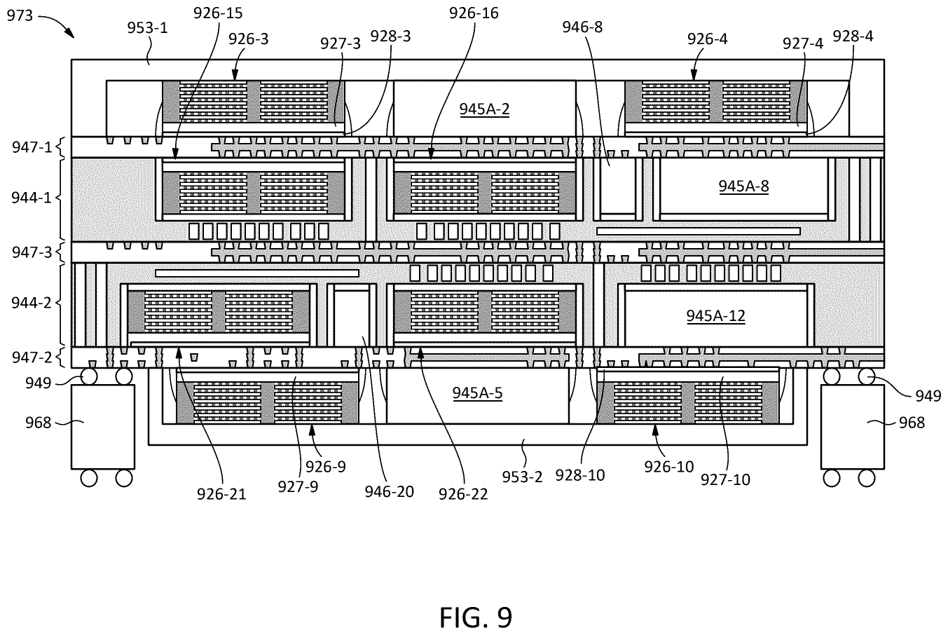

FIG. 9 illustrates an embodiment of a package architecture having two or more substrates in accordance with example embodiments of the disclosure. The package architecture 973 illustrated in FIG. 9 may include one or more elements that may be similar to those illustrated in FIGS. 6, 7, and/or 8, in which similar elements may be indicated by reference numbers ending in, and/or containing, the same digits, letters, and/or the like. However, the package architecture 973 illustrated in FIG. 9 may include two or more substrates 944-1 and 944-2. In some embodiments, the substrates 944 may be configured in a manner, including manners similar to any of the embodiments disclosed herein, and joined in any manner.

For example, the package architecture 973 illustrated in FIG. 9 may be configured in a manner similar to the package architecture 872 illustrated in FIG. 8 with a first substrate 944-1, but with an additional substrate 944-2 located between the first substrate 944-1 and the one or more components (e.g., multi-stack memory devices 926-9 and/or 926-10, and/or compute die 945A-5) located at the bottom of the package. The second substrate 944-2 may include one or more embedded components which, in the example illustrated in FIG. 9, may be implemented with one or more components (e.g., one or more multi-stack memory devices 926-21, 926-22 and/or one or more compute dies 945A-12, one or more power conditioning devices 946, as well as one or more thermal vias, thermal (e.g., cooling) channels, electrical vias, and/or the like) that may be arranged in a partial mirror image of similar components in the first substrate 944-1. In other embodiments, however, any numbers, types, and/or arrangement of embedded components may be used including one or more multi-stack memory devices (any number of which may be implemented with an interface die having a power distribution network that may be completely, mostly, or at least partially separated from one or more signal layers), compute dies, power conditioning devices, thermal structures, and/or the like.

Two or more substrates 944 may be connected in any suitable manner. For example, in the embodiment illustrated in FIG. 9, the first substrate 944-1 and the second substrate 944-2 may be connected by a third RDL 947-3. Thus, the three RDLs 947-1, 947-2, and/or 947-3 combined with vias in both substrates 944 may enable any component in the package architecture 973 to communicate with any other component in the package architecture 973.

Depending on the implementation details, the use of two or more substrates 944, one or more of which may include one or more embedded components, may reduce thermal dissipation, reduce the length of some connections, increase bandwidth, reduce delay, reduce power consumption, increase device packaging density (e.g., by accommodating more multi-stack memory devices 926) and/or the like.

Examples of applications for the aspects disclosed herein may include: CPUs, GPUs, AI chips (e.g., NPUs, TPUs, and/or the like), ASIC chips, and/or other applications that may benefit from increased memory bandwidth and/or high power; automotive and/or radio frequency (RF) chips that may benefit from greater reliability under relatively harsh operating conditions, datacenter applications that may benefit from larger packages, and/or the like.

The operations and/or structures illustrated and described herein are example operations and/or components shown in a sequence for purposes of illustration. However, in some embodiments, some operations and/or components may be omitted and/or other operations and/or components may be included. Moreover, in some embodiments, the temporal and/or spatial order of the operations and/or components may be varied. Although some components and/or operations may be illustrated as individual components, in some embodiments, some components and/or operations shown separately may be integrated into single components and/or operations, and/or some components and/or operations shown as single components and/or operations may be implemented with multiple components and/or operations.

Some embodiments disclosed above have been described in the context of various implementation details, but the principles of this disclosure are not limited to these or any other specific details. For example, some functionality has been described as being implemented by certain components, but in other embodiments, the functionality may be distributed between different systems and components in different locations and having various interfaces. Certain embodiments have been described as having specific processes, operations, etc., but these terms also encompass embodiments in which a specific process, operation, etc. may be implemented with multiple processes, operations, etc., or in which multiple processes, operations, etc. may be integrated into a single process, step, etc. A reference to a component or element may refer to only a portion of the component or element. For example, a reference to a block may refer to the entire block or one or more subblocks. The use of terms such as “first” and “second” in this disclosure and the claims may only be for purposes of distinguishing the elements they modify and may not indicate any spatial or temporal order unless apparent otherwise from context. In some embodiments, a reference to an element may refer to at least a portion of the element, for example, “based on” may refer to “based at least in part on,” and/or the like. A reference to a first element may not imply the existence of a second element. The principles disclosed herein have independent utility and may be embodied individually, and not every embodiment may utilize every principle. However, the principles may also be embodied in various combinations, some of which may amplify the benefits of the individual principles in a synergistic manner. The various details and embodiments described above may be combined to produce additional embodiments according to the inventive principles of this patent disclosure.

In some embodiments, a portion of an element may refer to less than, or all of, the element. A first portion of an element and a second portion of the element may refer to the same portions of the element. A first portion of an element and a second portion of the element may overlap (e.g., a portion of the first portion may be the same as a portion of the second portion).

Since the inventive principles of this patent disclosure may be modified in arrangement and detail without departing from the inventive concepts, such changes and modifications are considered to fall within the scope of the following claims.

1. A device comprising:
an interface die;
a first memory device stack connected to a first side of the interface die;
a second memory device stack connected to the first side of the interface die; and
a power distribution network located on a second side of the interface die.

2. The device of claim 1, wherein the power distribution network comprises:
a layer of conductive traces; and
a via arranged to transfer power using the layer of conductive traces.

3. The device of claim 1, wherein the interface die comprises:
a buffer circuit configured to access the first memory device stack; and
a processing circuit configured to perform an operation on data stored in the first memory device stack.

4. A system comprising:
a substrate comprising at least one distribution layer;
a compute die connected to the at least one distribution layer; and
a memory stack device connected to the at least one distribution layer, wherein the memory stack device comprises an interface die connected to the at least one distribution layer, a first stack of memory devices connected to the interface die, and a second stack of memory devices connected to the interface die.

5. The system of claim 4, wherein:
the substrate comprises an attachment location; and
the compute die is located within the attachment location.

6. The system of claim 4, wherein:
the substrate comprises an attachment location;
the compute die is located within the attachment location;
the memory stack device is connected to a first side of the distribution layer; and
the compute die is connected to a second side of the distribution layer.

7. The system of claim 6, wherein:
the memory stack device is a first memory stack device;
the system further comprises a second memory stack device connected to the first side of the distribution layer; and
the compute die is configured to connect the first memory stack device to the second memory stack device.

8. The system of claim 4, wherein:
the substrate comprises an attachment location; and
the memory stack device is located within the attachment location.

9. The system of claim 4, wherein:
the substrate comprises a first attachment location and a second attachment location;
the compute die is located in the first attachment location; and
the memory stack device is located in the second attachment location.

10. The system of claim 4, wherein:
the first stack of memory devices is connected to a first side of the interface die;
the second stack of memory devices is connected to the first side of the interface die;
the memory stack device comprises a power distribution network located on a second side of the interface die; and
the power distribution network is connected to the at least one distribution layer.

11. The system of claim 4, wherein:
one of the at least one distribution layer is located at a first side of the substrate; and
the substrate comprises a thermal structure located at a second side of the substrate.

12. The system of claim 4, wherein:
the memory stack device is a first memory stack device;
the system further comprises a second memory stack device;
the first memory stack device is located at a first side of the substrate; and
the second memory stack device is located at a second side of the substrate.

13. The system of claim 12, wherein:
the substrate comprises an attachment location;
the system further comprises a connecting element located within the attachment location; and
the connecting element is configured to connect the compute die and the first memory stack device.

14. The system of claim 12, wherein:
the substrate comprises an attachment location; and
the first memory stack device is located within the attachment location.

15. The system of claim 12, wherein:
the substrate comprises a first attachment location and a second attachment location;
the compute die is located in the first attachment location; and
the memory stack device is located in the second attachment location.

16. The system of claim 12, wherein the substrate is a first substrate, the system further comprising:
a second substrate located between the first substrate and the second memory stack device, wherein the second substrate comprises an attachment location; and
a third memory stack device located within the attachment location.

17. The system of claim 12, wherein the substrate is a first substrate, the system further comprising:
a second substrate located between the first substrate and the second memory stack device, wherein the second substrate comprises an attachment location; and
at least one of a compute die, connecting element, or power device located within the attachment location.

18. A method comprising:
forming, on a substrate, at least one distribution layer;
connecting, to the at least one distribution layer, a compute die; and
connecting, to the at least one distribution layer, a memory stack device comprising an interface die connected to the at least one distribution layer, a first stack of memory devices connected to the interface die, and a second stack of memory devices connected to the interface die.

19. The method of claim 18, further comprising:
forming, on a first side of the interface die, a power delivery network;
attaching, to a second side of the interface die, the first stack of memory devices; and
attaching, to the second side of the interface die, the second stack of memory devices.

20. The method of claim 18, wherein the memory stack device is a first memory stack device, the method further comprising:
positioning, at a first side of the substrate, the first memory device stack; and
positioning, at a second side of the substrate, a second memory device stack.
